(19) United States
(12) Patent Application Publication
(10) Pub. No.: US 2013/0146134 A1
(43) Pub. Date: Jun. 13, 2013

(54) SOLAR CELL WITH NANOLAMINATED TRANSPARENT ELECTRODE AND METHOD OF MANUFACTURING THE SAME

(71) Applicants: CHIEN-NAN HSIAO, Hsinchu (TW); Chih-Chieh Yu, Hsinchu (TW); Po-Kai Chiu, Hsinchu (TW); Chi-Chung Kei, Hsinchu (TW); Don-Yau Chiang, Hsinchu (TW)

(72) Inventors: CHIEN-NAN HSIAO, Hsinchu (TW); Chih-Chieh Yu, Hsinchu (TW); Po-Kai Chiu, Hsinchu (TW); Chi-Chung Kei, Hsinchu (TW); Don-Yau Chiang, Hsinchu (TW)

(73) Assignee: National Applied Research Laboratories, Taipei (TW)

(21) Appl. No.: 13/402,823

(22) Filed: Feb. 22, 2012

(30) Foreign Application Priority Data
Dec. 13, 2011 (TW) 100146066

(51) Int. Cl. H01L 31/0224; H01L 31/18

(52) U.S. Cl. 136/256; 438/98; 257/E31.124

(57) ABSTRACT

The present invention discloses a solar cell with a nanolaminated transparent electrode and a method of manufacturing the same. The solar cell comprises a substrate, a first electrode layer deposited on the substrate, a photovoltaic layer deposited on the first electrode layer, and a second electrode layer deposited on the photovoltaic layer. Wherein, at least one of the first and second electrode layers is a nanolaminated transparent electrode prepared by using atomic layer deposition (ALD). The nanolaminated transparent electrode may serve as both of the transparent electrode and the anti-reflective layer and is able to maintain good transmittance in infrared wavelength.

### CROSS-REFERENCE TO RELATED APPLICATION

This application claims the benefit of Taiwan Patent Application No. 100146066, filed on Dec. 13, 2011, in the Taiwan Intellectual Property Office, the disclosure of which is incorporated herein in its entirety by reference.

### BACKGROUND OF THE INVENTION

1. Field of the Invention

The present invention relates to a solar cell, and more particularly to the solar cell with nanolaminated transparent electrode and a method of manufacturing the same, such that the solar cell can have good transmittance in infrared wavelength.

2. Description of Related Art

As non-exhaustive solar energy becomes an important substitute energy source in the present energy crisis, fuel shortage, and environmental pollution conditions, the research and attempt of utilizing solar energy have gain increasingly more attention. However, the scope of applicability of the solar energy is limited by the production capacity and efficiency of solar cells. Therefore, it is an important subject to improve the photoelectric conversion efficiency to enhance the performance of the solar cells.

To reduce the reflection loss of incident sunlight, it is necessary for the present solar cells to add a process of depositing a silicon nitride film, and this process adopts a highly hazardous chemical, silane as a raw material, and thus incurring a high cost to maintain the industrial safety. In the meantime, a high-temperature sintering process is a metallization process (also known as screen printing) required for sintering the conductive metal slurry, and this high-temperature process usually causes a bowing phenomenon of the solar chips, resulting in a large amount of fragments produced by the solar chips in the following manufacturing process. The bowing condition becomes more serious with an increased thinness of the future solar chips. In addition, the finger-shaped silver conductive wires on the front side of the solar cell also become the resistors (Rs) in series and affect the power supply efficiency of the solar cell. In the operation of the solar cell, a portion of the light receiving area of the front side will be shaded by the silver conductive wire, so that a general design will minimizes the wire width of the finger and busbar. However, a too-narrow busbar will cause tremendous difficulty for the operation when the conductive wire is soldered onto the module. In the meantime, a too-small soldering area will cause an increase of contact resistance and a poor soldering strength between the conductive wire and the busbar. A reduction in wire width of the finger can decrease the shading percentage directly, but the resistance Rs will increase and lower the photoelectric conversion efficiency, so that cautions are required for a good quality of the screen printing of the silver conductive wires. The organic solutes added in the conductive slurry during the sintering process will also cause industrial safety issues such as contaminating the environment and jeopardizing the respiratory organs of the work staffs.

Therefore, it is a main subject for the present invention to overcome the shortcomings of the conventional solar cell transparent electrode by providing a solar cell with a nanolaminated anti-reflective transparent electrode that features a lower cost, a higher safety and the potential for mass production.

### SUMMARY OF THE INVENTION

In view of the aforementioned problems of the prior art, it is a primary objective of the invention to overcome the shortcomings by providing a solar cell with a nanolaminated transparent electrode and a method of manufacturing the same, so as to enhance the photoelectric conversion efficiency.

To achieve the aforementioned objectives, the present invention provides a solar cell with nanolaminated transparent electrode, comprising: a substrate; a first electrode layer, disposed on the substrate; a photovoltaic layer, disposed on the first electrode layer; and a second electrode layer, disposed on the photovoltaic layer.

Wherein, at least one of the first electrode layer and the second electrode layer has a nanolaminated transparent electrode, and the nanolaminated transparent electrode includes a plurality of nano composite layers, and each of the nano composite layers comprises: a plurality of first metal oxide layers; and a plurality of second metal oxide layers, formed on the first metal oxide layers.

Wherein, the first metal oxide layers and the second metal oxide layers are made of different materials, which is selected from the collection of zinc oxide, titanium-aluminum oxide, aluminum oxide, indium oxide, titanium oxide, manganese oxide, germanium oxide and germanium-indium oxide, and a spinel phase layer is formed at a contact interface of the first metal oxide layers and the second metal oxide layers.

Preferably, when the first metal oxide layer or the second metal oxide layer is a zinc oxide layer, the zinc oxide layer has a thickness of 1.7 to 2 Å.

Preferably, when the first metal oxide layer or the second metal oxide layer is an aluminum oxide layer, the aluminum oxide layer has a thickness of 0.9 to 1.1 Å.

Preferably, the aluminum oxide layer and the zinc oxide layer in each nano composite layer have the numbers of layers in a ratio of 2:98 to 5:95.

Preferably, when the plurality of nano composite layers are laminated to 850˜950 layers, the nanolaminated transparent electrode has a sheet resistance less than 50 Ω/□, and an average transmittance up to 85% within a wavelength ranging from 400˜1300 nm.

Preferably, the spinel phase layer has an average density of 5.5 g/cm³ to 7.2 g/cm³.

In addition, the present invention further provides a method of manufacturing a solar cell with a nanolaminated transparent electrode, and the method comprises the steps of: preparing a substrate; forming a first electrode layer on the substrate; forming a photovoltaic layer on the first electrode layer; and forming a second electrode layer on the photovoltaic layer; wherein, at least one of the first electrode layer and the second electrode layer has a nanolaminated transparent electrode manufactured by an atomic layer deposition (ALD) method, and processed repeatedly by a super cycle procedure to form a plurality of nano composite layers on the photovoltaic layer, and the super cycle procedure comprises the steps of: repeating a first unit cycle procedure to form a plurality of first metal oxide layers; and repeating a second unit cycle procedure to form a plurality of second metal oxide layers; wherein the first metal oxide layers and the second metal oxide layers are made of different materials, and the first and second unit cycle procedures are conducted in a reaction chamber, and a reaction pressure of the reaction chamber, a reaction temperature of the substrate, and a ratio of the numbers of layers of the first metal oxide layer and the second metal oxide layer in each nano composite layer are controlled, such that a spinel phase layer is formed at a contact interface of the first metal oxide layer and the second metal oxide layer.

Preferably, the first metal oxide layer is one selected from the collection of a zinc oxide layer, a titanium-aluminum oxide layer, an aluminum oxide layer, an indium oxide layer, a titanium oxide layer, a manganese oxide layer, a germanium oxide layer and a germanium-indium oxide layer.

Preferably, the second metal oxide layer is one selected from the collection of a zinc oxide layer, a titanium-aluminum oxide layer, an aluminum oxide layer, an indium oxide layer, a titanium oxide layer, a manganese oxide layer, a germanium oxide layer and a germanium-indium oxide layer.

Preferably, when the first metal oxide layer or the second metal oxide layer is a zinc oxide layer, the zinc oxide layer has a thickness of 1.7 to 2 Å.

Preferably, when the first metal oxide layer or the second metal oxide layer is an aluminum oxide layer, the aluminum oxide layer has a thickness of 0.9 to 1.1 Å.

Preferably, the reaction pressure is ranging from 2 Torr to 14 Torr, and the temperature of the substrate is ranging from 100 to 250.

Preferably, the aluminum oxide layer and the zinc oxide layer of each nano composite layer have the numbers of layers in a ratio of 2:98 to 5:95.

Preferably, if the plurality of nano composite layers are laminated to 850˜950 layers, the nanolaminated transparent electrode has a sheet resistance less than 50 Ω/□ and an average transmittance up to 85% within a wavelength ranging from 400˜1300 nm.

In summation, the solar cell with a nanolaminated transparent electrode and the method of manufacturing the same in accordance with the present invention have one or more of the following advantages:

(1) The nanolaminated transparent electrode of the solar cell of the present invention can overcome the complicated silicon nitrate anti-reflective film with a safety concern, while playing the roles of the transparent electrode and the anti-reflective film of the solar cell to achieve the effects of simplifying manufacturing process, saving manufacturing cost, and improving safety.

(2) The nanolaminated transparent electrode of the solar cell of the present invention no longer requires the metallization process, thus is able to avoid shading caused by the silver conductive wires, increase the light receiving area of the solar cell, and enhance the photoelectric conversion efficiency.

(3) The nanolaminated transparent electrode of the solar cell of the present invention is prepared by the atomic layer deposition (ALD) method, which is able to accurately control the film thickness, and the drift rate of the film thickness is less than 1%, and such precision process of the atomic scale can reduce the atom agglomeration phenomenon to lower the surface roughness and reduce the surface and interface scattering, so as to enhance the optical properties. On the other hand, the conductivity can be improved, since the structural defect of the film, the carrier trap center, and the defect scattering center are lower than those manufactured by the conventional processes.

(4)The nanolaminated transparent electrode of the solar cell of the present invention is optimized by the optical design, so that a light transmittance up to 85% can be maintained within the range of infrared wavelength of 770˜1300 nm, so as to enhance the efficiency of the solar cell.

### BRIEF DESCRIPTION OF THE DRAWINGS

FIG. 1 is a schematic structural view of a nanolaminated transparent electrode of the present invention;

FIG. 2 is a flow chart of a super cycle of a method of manufacturing a nanolaminated transparent electrode in accordance to the present invention;

FIG. 3 is a flow chart of a first unit cycle of a method of manufacturing a nanolaminated transparent electrode in accordance to the present invention;

FIG. 4 is a flow chart of a second unit cycle of a method of manufacturing a nanolaminated transparent electrode in accordance to the present invention;

FIG. 5 is a cross-sectional view of a solar cell with a nanolaminated transparent electrodes in accordance with a first preferred embodiment of the present invention;

FIG. 6 is a cross-sectional view of a solar cell with a nanolaminated transparent electrodes in accordance with a second preferred embodiment of the present invention;

FIG. 7 is a cross-sectional view of a solar cell with a nanolaminated transparent electrodes in accordance with a third preferred embodiment of the present invention;

FIG. 8 is a flow chart of a method of manufacturing a solar cell with a nanolaminated transparent electrode in accordance with the present invention;

FIG. 9 is a wavelength versus transmittance graph of an aluminum oxide layer in the total number of layers of a nanolaminated transparent electrode of the present invention; and

FIG. 10 is a resistance versus deposition cycle graph, showing the relation between the number of laminates and sheet resistance of a nanolaminated transparent electrode of the present invention.

### DETAILED DESCRIPTION OF THE PREFERRED EMBODIMENTS

The technical contents and characteristics of the present invention will be apparent with the detailed description of a preferred embodiment accompanied with related drawings as follows. For simplicity, same numerals are used in the following preferred embodiment to represent respective same elements.

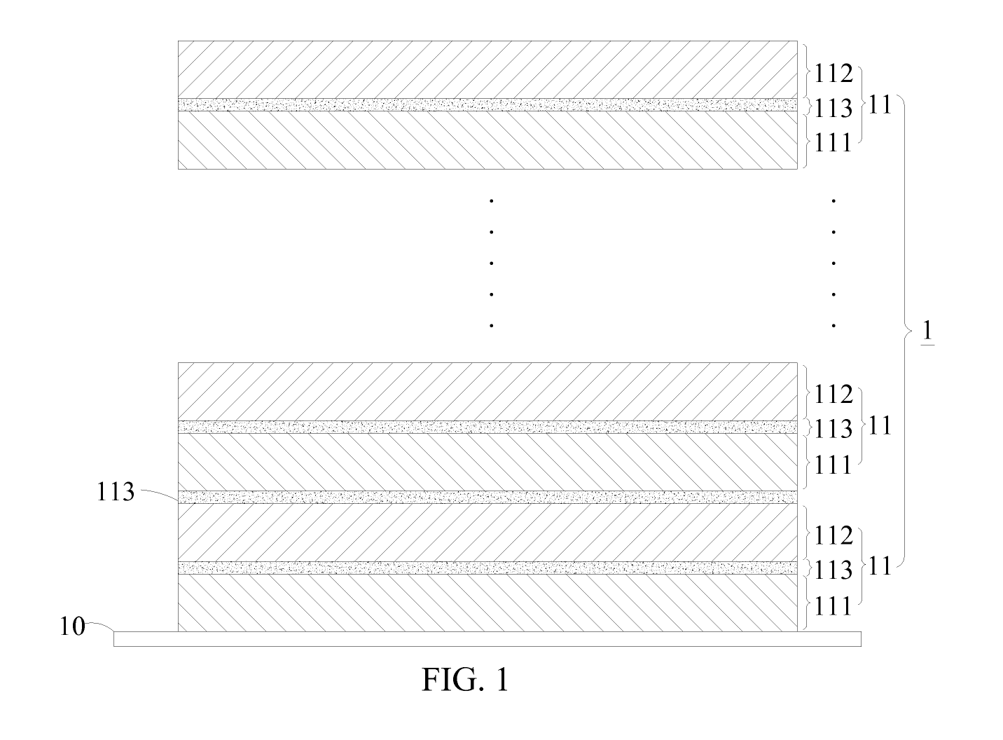

With reference to FIG. 1 for a schematic structural view of a nanolaminated transparent electrode of the present invention, the nanolaminated transparent electrode 1 includes a nano composite layer 11 laminated repeatedly and formed on a surface of a substrate 10 to achieve the anti-reflection effect and the conduction effect. Each nano composite layer 11 comprises a plurality of first metal oxide layers 111 and a plurality of second metal oxide layers 112, and the plurality of second metal oxide layers 112 are formed on the plurality of first metal oxide layers 111. Wherein, each nano composite layer 11 has a spinel phase layer 113 formed at a contact interface of the plurality of first metal oxide layers 111 and the plurality of second metal oxide layers 112. Similarly, two laminated nano composite layers in which the plurality of first metal oxide layers 111 of a nano composite layer are stacked on the second metal oxide layer 112 of another nano metal layer and deposited on the substrate 10, so that a spinel phase layer 113 is also formed between two laminated nano composite layers.

In addition, the nanolaminated transparent electrode 1 as shown in FIG. 1 may further comprise a plurality of second metal oxide layers formed and covered onto the top layer of the nano composite layers, if necessary.

In the nanolaminated transparent electrode 1 of the present invention, the first metal oxide layer 111 and the second metal oxide layer 112 are made of different materials. The first metal oxide layer 111 is a transparent and conductive metal oxide layer, such as a zinc oxide (ZnO) layer, an aluminum oxide (Al₂O₃) layer, an indium oxide layer, a titanium oxide layer, a manganese oxide layer, a germanium oxide layer or a germanium-indium oxide layer, and the second metal oxide layer 112 is also a transparent metal oxide layer such as a zinc oxide layer, an aluminum oxide (Al₂O₃) layer, an indium oxide layer, a titanium oxide layer, a manganese oxide layer, a germanium oxide layer or a germanium-indium oxide layer. The substrate 10 can be a solar cell substrate made of glass or stainless steel, or the surface of the top layer of the photovoltaic layer of the solar cell.

The nanolaminated transparent electrode 1 of the present invention is mainly manufactured by an atomic layer deposition (ALD) process. In the manufacturing process, the deposition conditions of the first metal oxide layer 111 and the second metal oxide layer 112 are controlled to form a thin film with optimal roughness, density and thickness, and to form spinel phase layers 113 with high density between different metal oxide layers, and the spinel phase layer has a density ranging from 5.5 g/cm³ to 7.2 g/cm³ according to the types of the first metal oxide layer 111 and the second metal oxide layer 112. Compared with the nanolaminated film manufactured by the conventional manufacturing process, the present invention can obtain the optimal roughness and density for surfaces of each layer of the nanolaminated transparent electrode through the atomic layer deposition (ALD) and form the spinel phase layers. Therefore, the nanolaminated composite layers can be stacked to reduce the surface and interface scattering caused by the rough surface of the thin film, so that the nanolaminated transparent electrode of the present invention can achieve the anti-reflection effect efficiently. In addition, the atomic layer deposition (ALD) forms the thin film structure by a chemical adsorption process, so that a thin film with a more uniform thickness can be formed, so that the total thickness of the thin film can be reduced, which is more advantageous to be applied in thin film solar cells.

In the method of manufacturing a nanolaminated transparent electrode in accordance with the present invention, a super cycle procedure is performed on the substrate 10 to form the first layer of the nano composite layer 11, and then the super cycle procedure is repeated on the substrate 10 for several times to form a plurality of nano composite layers 11.

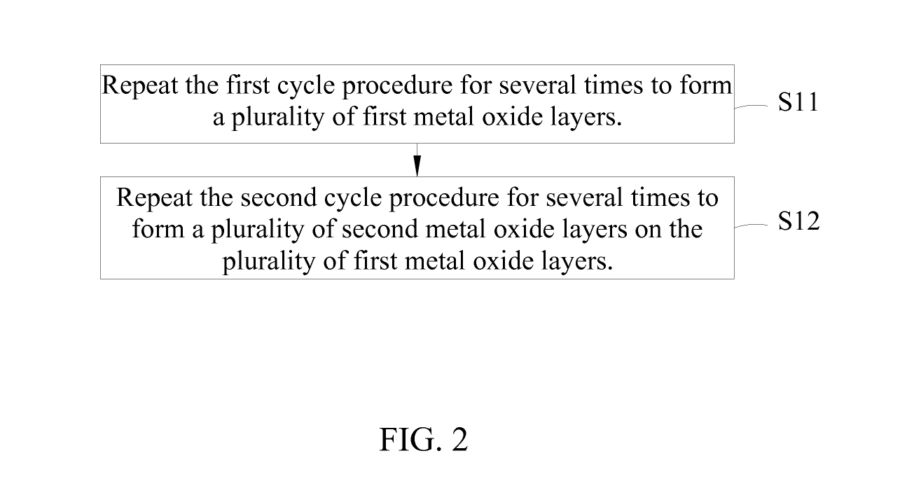

With reference to FIG. 2 for a flow chart of a super cycle of a method of manufacturing a nanolaminated transparent electrode in accordance to the present invention, each super cycle procedure comprises the following steps:

Step S11: Repeat the first cycle procedure for several times to form a plurality of first metal oxide layers.

Step S12: Repeat the second cycle procedure for several times to form a plurality of second metal oxide layers on the plurality of first metal oxide layers. Wherein, a single first metal oxide layer is formed in the first-time first unit cycle procedure, and a single second metal oxide layer is formed in the next second unit cycle.

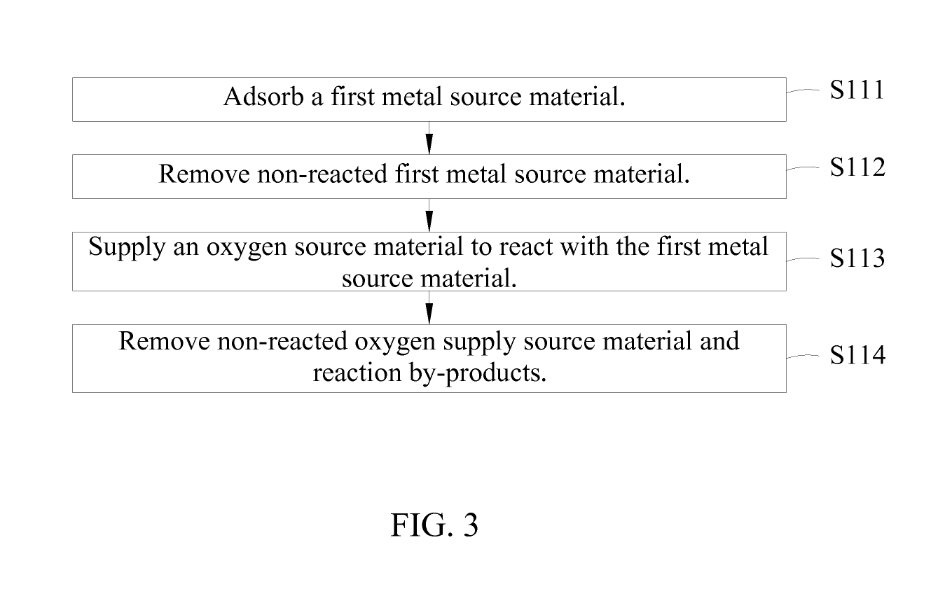

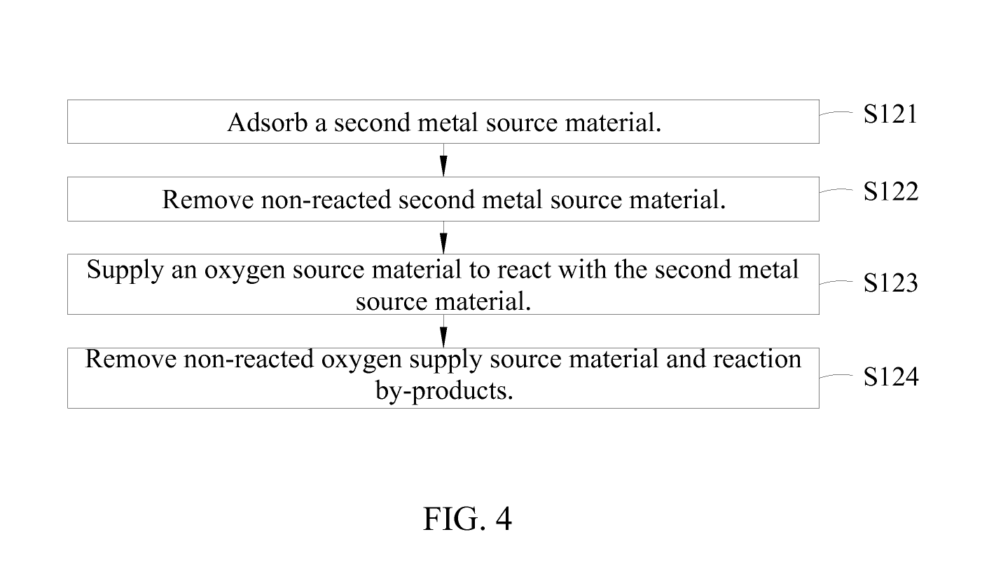

With reference to FIGS. 3 and 4 for flow charts of the first and second unit cycles of a method of manufacturing a nanolaminated transparent electrode in accordance to the present invention respectively, the first unit cycle comprises the following steps:

Step S111: Adsorb a first metal source material.

Step S112: Remove non-reacted first metal source material.

Step S113: Supply an oxygen source material to react with the first metal source material.

Step S114: Remove non-reacted oxygen supply source material and reaction by-products.

The second unit cycle of the present invention comprises the following steps:

Step S121: Adsorb a second metal source material.

Step S122: Remove non-reacted second metal source material.

Step S123: Supply an oxygen source material to react with the second metal source material.

Step S124: Remove non-reacted oxygen supply source material and reaction by-products.

If the first metal oxide layer 111 and the second metal oxide layer 112 are zinc oxide (ZnO) layer, aluminum oxide layer, indium oxide layer, titanium oxide layer, manganese oxide layer, germanium oxide layer or germanium-indium oxide layer, the first metal source and second metal source can be organic metal sources such as zinc, aluminum, indium, titanium, manganese, germanium, or germanium-indium metal. The supplied oxygen source material can be O₃, H₂O or O₂ plasma, and is used to oxidize the first metal source or the second metal source adsorbed on the surface of the substrate to form a first metal oxide layer or a second metal oxide layer respectively. In addition, the supply of nitrogen gas or inert gas into the reaction chamber of the atomic layer deposition (ALD) as described in Steps S112, S114, S122 and S124 can remove non-reacted first metal source material, second metal source material, oxygen supply source material and reaction by-product.

The first to third preferred embodiments of the present invention are provided for illustrating the applications of the nanolaminated transparent electrode of the present invention in a solar cell as follows.

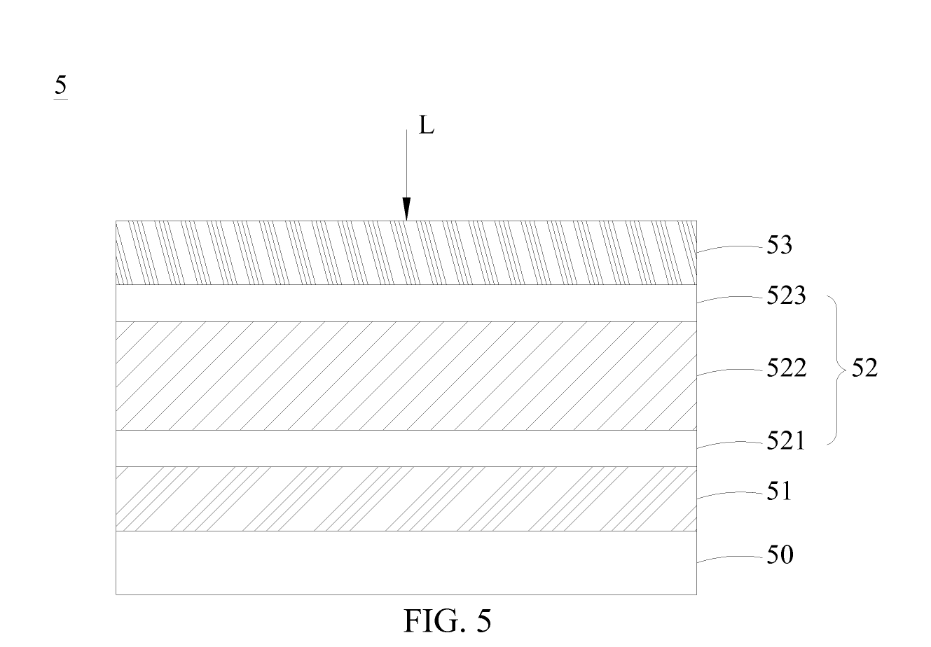

With reference to FIG. 5 for a cross-sectional view of a solar cell with a nanolaminated transparent electrode in accordance with the first preferred embodiment of the present invention, the solar cell 5 comprises a transparent insulating substrate 50, a first electrode layer 51, a photovoltaic layer 52 and a second electrode layer 53.

Wherein, the transparent insulating substrate 50 is a glass substrate, and the first electrode layer 51 is a metal electrode layer, and the photovoltaic layer 52 can be a p-i-n structure or an n-i-p structure, wherein 522 of the figure indicates an absorber layer (which is the i layer), and 521 and 523 indicate the n/p layer or p/n layer. The second electrode 53 is the nanolaminated transparent electrode of the present invention and comprises a plurality of nano composite layers, and each nano composite layer comprises a plurality of first metal oxide layers and a plurality of second metal oxide layers formed on the first metal oxide layers. Wherein, zinc oxide (ZnO) is used as the first metal oxide layer, and aluminum oxide (Al₂O₃) is used as the second metal oxide layer.

In the figure, sunlight L is incident into the solar cell 5 in a direction indicated by the arrow, and the sunlight L passes through the second electrode layer 53 with the anti-reflection effect, and electrons and electron holes are formed at the photovoltaic layer 52, and then outputted from the first electrode layer 51 and the second electrode layer 53. Wherein, when the plurality of nano composite layers of the second electrode layer 53 are stacked to 850˜950 layers, the second electrode layer 53 may have a sheet resistance lower than 50 Ω/□, and an average transmittance up to 85% within the wavelength ranging from 400˜1300 nm.

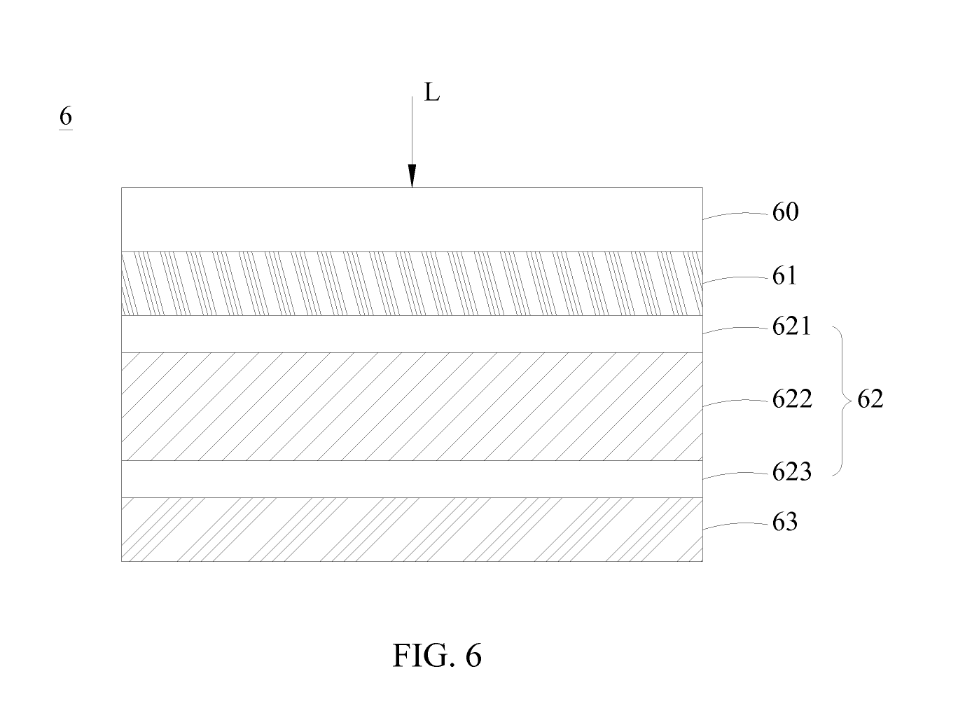

With reference to FIG. 6 for a cross-sectional view of a solar cell with a nanolaminated transparent electrode in accordance with the second preferred embodiment of the present invention, the solar cell 6 comprises a transparent insulating substrate 60, a first electrode layer 61, a photovoltaic layer 62 and a second electrode layer 63. Wherein, the transparent insulating substrate 60 can be a glass substrate, and the second electrode layer 63 can be a metal electrode layer, and the photovoltaic layer 62 can have a p-i-n structure or an n-i-p structure, wherein 622 of the figure indicates an absorber layer (which is the i layer, and 621 and 623 indicated the required n/p layer or p/n layer. The first electrode 61 is the nanolaminated transparent electrode of the present invention and comprises a plurality of nano composite layers, and each nano composite layer comprises a plurality of first metal oxide layers, and a plurality of second metal oxide layers formed on the first metal oxide layers. Wherein, zinc oxide (ZnO) is used as the first metal oxide layer and aluminum oxide (Al₂O₃) as the second metal oxide layer.

In the figure, sunlight L is incident into the solar cell 6 in a direction indicated by the arrow, and the sunlight L passes through the transparent insulating substrate 60 and the first electrode layer 61 with the anti-reflection effect, and electrons and electron holes are formed at the photovoltaic layer 62 and outputted from the first electrode layer 61 and the second electrode layer 63.

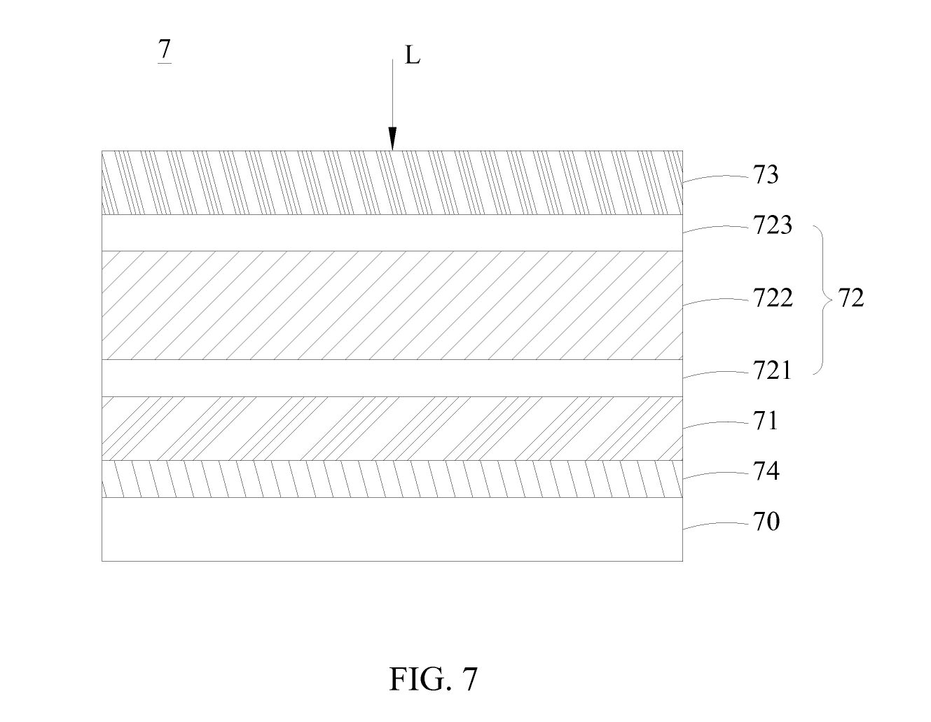

With reference to FIG. 7 for a cross-sectional view of a solar cell with a nanolaminated transparent electrode in accordance with the third preferred embodiment of the present invention, the solar cell 7 comprises a metal substrate 70, an insulating layer 74, a first electrode layer 71, a photovoltaic layer 72 and a second electrode layer 73. Wherein, the metal substrate 70 is a stainless steel plate, and the first electrode layer 71 is a metal electrode layer, and the photovoltaic layer 72 can be designed with a p-i-n structure or an n-i-p structure, wherein 722 in the figure indicates an absorber layer (which is the i layer), and 721 and 723 indicate the required n/p layer or p/n layer. The second electrode 73 is the nanolaminated transparent electrode of the present invention comprising a plurality of nano composite layers, and each nano composite layer comprises a plurality of first metal oxide layers, and a plurality of second metal oxide layers formed on the first metal oxide layers. Wherein, zinc oxide (ZnO) is used as the first metal oxide layer, and aluminum oxide (Al₂O₃) is used as the second metal oxide layer.

In the figure, sunlight L is incident into the solar cell 7 in a direction indicated by the arrow, and the sunlight L passes through the second electrode layer 73 with the anti-reflection effect, and then electrons and electron holes are formed at the photovoltaic layer 72 and outputted from the first electrode layer 71 and the second electrode layer 73.

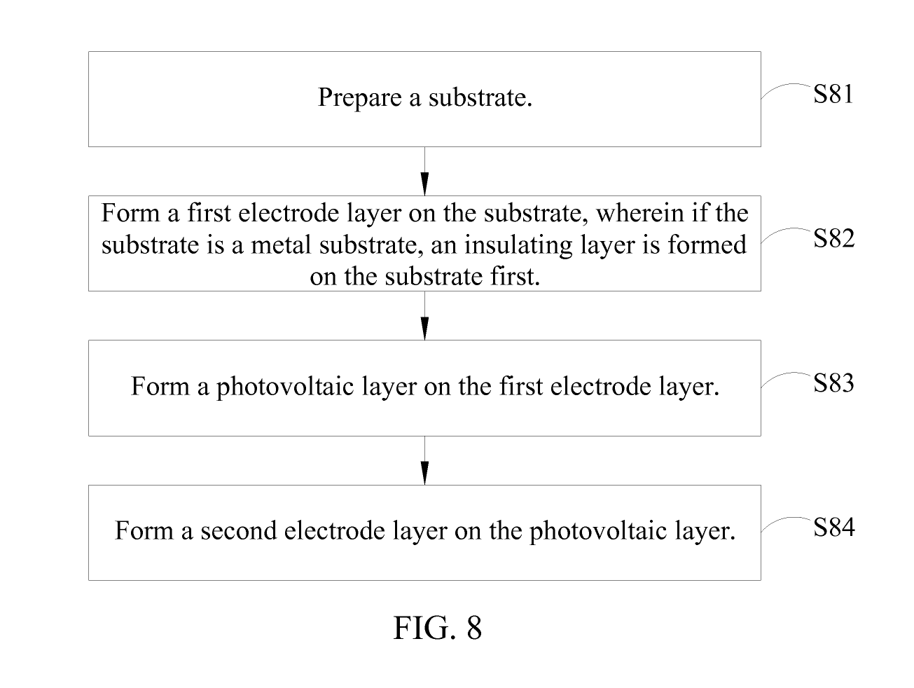

With reference to FIG. 8 for a flow chart of a method of manufacturing a solar cell with a nanolaminated transparent electrode in accordance with the present invention, the method comprises the following steps:

S81: Prepare a substrate.

S82: Form a first electrode layer on the substrate, wherein when the substrate is a metal substrate, an insulating layer is formed on the substrate first.

S83: Form a photovoltaic layer on the first electrode layer.

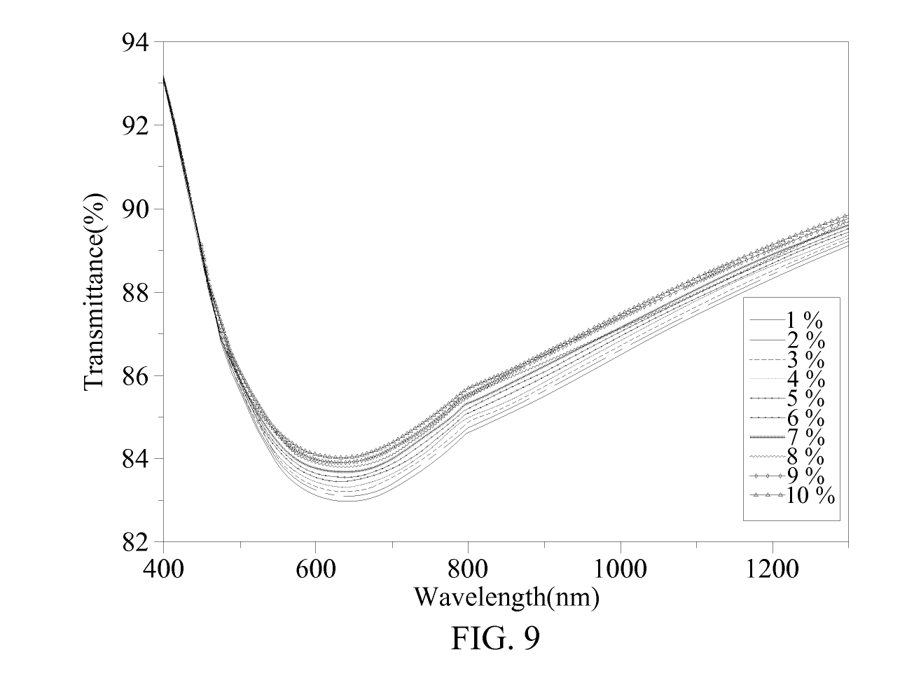

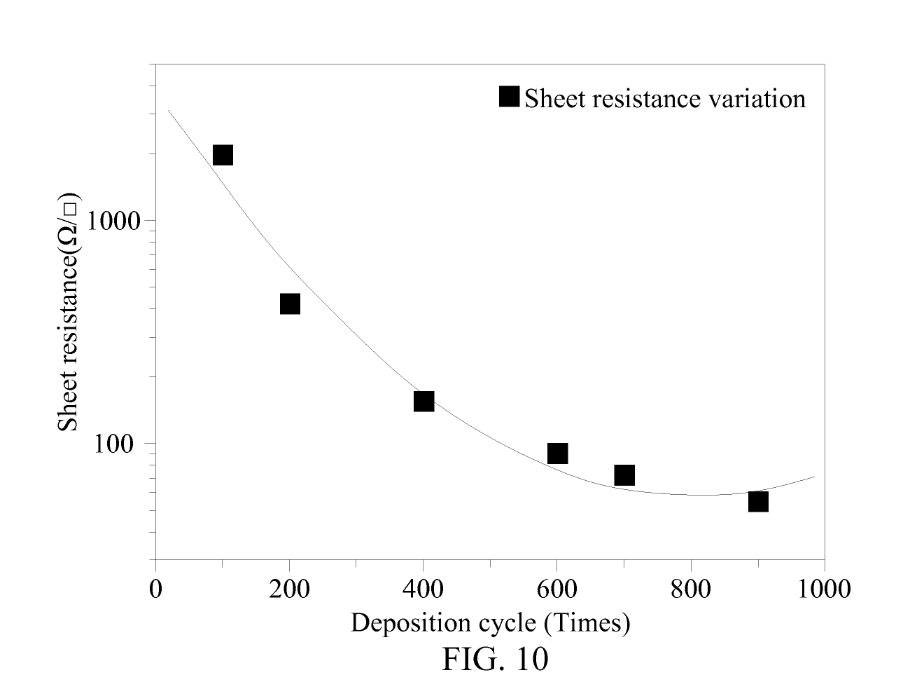

S84: Form a second electrode layer on the photovoltaic layer.

Wherein, the photovoltaic layer can have a p-i-n structure or an n-i-p structure, and at least one of the first electrode layer and the second electrode layer has a nanolaminated transparent electrode manufactured by the atomic layer deposition (ALD) method. The procedure is the same as described above and illustrated by FIGS. 2 and 4, and thus will not be described again. It is noteworthy to point out that the first metal oxide layer and the second metal oxide layer in the nanolaminated transparent electrode have the numbers of layers in a ratio. For example, these two layers are aluminum oxide layer and zinc oxide layer respectively, and when the number of aluminum oxide layers increases, the light transmittance of the transparent electrode also increases as shown in FIG. 9, but on the other hand, the sheet resistance may also increase. Therefore, an ideal ratio of the numbers of these two layers is 2:98 to 5:95. In addition, the number of laminates of the nanolaminated transparent electrode also has an effect on the spectral range and the sheet resistance. For example, when the number of laminates falls within a range of 100˜700 layers, the spectral range only covers a range of 400˜1000nm, and with the increase of the number of laminates, the sheet resistance of the transparent electrode drops gradually as shown in FIG. 10. Taking the conditions of the spectral range, the average transmittance and the sheet resistance into consideration, the present invention sets the number of laminates to approximately 850˜950 layers, so as to achieve the effect of maintaining the sheet resistance of the present invention below 50 Ω/□, while achieving an average transmittance up to 85% within the wavelength ranging from 400˜1300 nm.

While the means of specific embodiments in the present invention has been described by reference drawings, numerous modifications and variations could be made thereto by those skilled in the art without departing from the scope and spirit of the invention set forth in the claims. The modifications and variations should be in a range limited by the specification of the present invention.

What is claimed is:

1. A solar cell with a nanolaminated transparent electrode, comprising:
a substrate;
a first electrode layer, disposed on the substrate;
a photovoltaic layer, disposed on the first electrode layer; and
a second electrode layer, disposed on the photovoltaic layer;
wherein, at least one of the first electrode layer and the second electrode layer has a nanolaminated transparent electrode, and the nanolaminated transparent electrode includes a plurality of nano composite layers, and each of the nano composite layers comprises:
a plurality of first metal oxide layers; and
a plurality of second metal oxide layers, formed on the first metal oxide layers;
wherein, the first metal oxide layers and the second metal oxide layers comprise different materials, and a spinel phase layer is formed at a contact interface of the first metal oxide layers and the second metal oxide layers.

2. The solar cell of claim 1, wherein the first metal oxide layer is one selected from the collection of a zinc oxide layer, a titanium-aluminum oxide layer, an aluminum oxide layer, an indium oxide layer, a titanium oxide layer, a manganese oxide layer, a germanium oxide layer and a germanium-indium oxide layer.

3. The solar cell of claim 1, wherein the second metal oxide layer is one selected from the collection of a zinc oxide layer, a titanium-aluminum oxide layer, an aluminum oxide layer, an indium oxide layer, a titanium oxide layer, a manganese oxide layer, a germanium oxide layer and a germanium-indium oxide layer.

4. The solar cell of claim 1, wherein when the first metal oxide layer or the second metal oxide layer is a zinc oxide layer, the zinc oxide layer has a thickness of 1.7 to 2 Å.

5. The solar cell of claim 4, wherein when the first metal oxide layer or the second metal oxide layer is an aluminum oxide layer, the aluminum oxide layer has a thickness of 0.9 to 1.1 Å.

6. The solar cell of claim 5, wherein the aluminum oxide layer and the zinc oxide layer in each of the nano composite layers have the numbers of layers in a ratio of 2:98 to 5:95.

7. The solar cell of claim 6, wherein when the nano composite layers are laminated to 850˜950 layers, the nanolaminated transparent electrode has a sheet resistance less than 50 Ω/□, and an average transmittance up to 85% within a wavelength ranging from 400˜1300 nm.

8. The solar cell of claim 6, wherein the spinel phase layer has an average density of 5.5 g/cm³ to 7.2 g/cm³.

9. A method of manufacturing a solar cell, comprising the steps of:
preparing a substrate;
forming a first electrode layer on the substrate;
forming a photovoltaic layer on the first electrode layer; and
forming a second electrode layer on the photovoltaic layer;
wherein, at least one of the first electrode layer and the second electrode layer has a nanolaminated transparent electrode manufactured by an atomic layer deposition (ALD) method, and processed repeatedly by a super cycle procedure to form a plurality of nano composite layers on the photovoltaic layer, and the super cycle procedure comprises the steps of:
repeating a first unit cycle procedure to form a plurality of first metal oxide layers; and
repeating a second unit cycle procedure to form a plurality of second metal oxide layers;
wherein the first metal oxide layers and the second metal oxide layers comprise different materials, and the first and second unit cycle procedures are conducted in a reaction chamber, and a reaction pressure of the reaction chamber, a reaction temperature of the substrate, and a ratio of the numbers of layers of the first metal oxide layer and the second metal oxide layer in each of the nano composite layers are controlled, such that a spinel phase layer is formed at a contact interface of the first metal oxide layer and the second metal oxide layer.

10. The method of manufacturing a solar cell as recited in claim 9, wherein the first metal oxide layer is one selected from the collection of a zinc oxide layer, a titanium-aluminum oxide layer, an aluminum oxide layer, an indium oxide layer, a titanium oxide layer, a manganese oxide layer, a germanium oxide layer and a germanium-indium oxide layer.

11. The method of manufacturing a solar cell as recited in claim 9, wherein the second metal oxide layer is one selected from the collection of a zinc oxide layer, a titanium-aluminum oxide layer, an aluminum oxide layer, an indium oxide layer, a titanium oxide layer, a manganese oxide layer, a germanium oxide layer and a germanium-indium oxide layer.

12. The method of manufacturing a solar cell as recited in claim 9, wherein when the first metal oxide layer or the second metal oxide layer is a zinc oxide layer, the zinc oxide layer has a thickness of 1.7 to 2 Å.

13. The method of manufacturing a solar cell as recited in claim 12, wherein when the first metal oxide layer or the second metal oxide layer is an aluminum oxide layer, the aluminum oxide layer has a thickness of 0.9 to 1.1 Å.

14. The method of manufacturing a solar cell as recited in claim 13, wherein the reaction pressure is ranging from 2 Torr to 14 Torr, and the temperature of the substrate is ranging from 100 to 250.

15. The method of manufacturing a solar cell as recited in claim 14, wherein the aluminum oxide layer and the zinc oxide layer in each of the nano composite layers have the numbers of layers in a ratio of 2:98 to 5:95.

16. The method of manufacturing a solar cell as recited in claim 14, wherein when the plurality of nano composite layers are laminated to 850˜950 layers, the nanolaminated transparent electrode has a sheet resistance less than 50 Ω/□and an average transmittance up to 85% within a wavelength ranging from 400˜1300 nm.
